(19) United States
(12) Patent Application Publication
(10) Pub. No.: US 2024/0304222 A1
(43) Pub. Date: Sep. 12, 2024

(54) SEMICONDUCTOR MEMORY DEVICE AND CONTROL METHOD

(71) Applicant: Nuvoton Technology Corporation Japan, Kyoto (JP)

(72) Inventor: Atsushi MOTOTANI, Osaka (JP)

(21) Appl. No.: 18/670,302

(22) Filed: May 21, 2024

Related U.S. Application Data
(63) Continuation of application No. PCT/JP2022/043303, filed on Nov. 24, 2022.

(30) Foreign Application Priority Data
Dec. 8, 2021 (JP) 2021-199650

(51) Int. Cl. G11C 5/14; G11C 11/419

(52) U.S. Cl. CPC G11C 5/148; G11C 11/419

(57) ABSTRACT

A semiconductor memory device includes memory cells, a first power supply line, a second power supply line, a first transistor and a second transistor that are connected in parallel between the first power supply line and the second power supply line, and a control circuit. In accordance with a first signal for switching between a first mode and a second mode, the control circuit (i) switches off the first transistor and the second transistor in the period of the second mode and (ii) switches on the first transistor when switching from the second mode to the first mode is performed and switches on the second transistor after the first transistor is switched on, the first mode being a mode for supplying the power supply voltage to the memory cells, the second mode being a mode for not supplying the power supply voltage to memory cells.

### CROSS REFERENCE TO RELATED APPLICATIONS

This is a continuation application of PCT International Application No. PCT/JP2022/043303 filed on Nov. 24, 2022, designating the United States of America, which is based on and claims priority of Japanese Patent Application No. 2021-199650 filed on Dec. 8, 2021. The entire disclosures of the above-identified applications, including the specifications, drawings and claims are incorporated herein by reference in their entirety.

### FIELD

The present disclosure relates to a semiconductor memory device and a control method.

### BACKGROUND

There is a known technique of suppressing current consumption by cutting off a power supply when a circuit block in a semiconductor memory device such as static random access memory (SRAM) is in a standby state. A peak current increases when the circuit block wakes up from the standby state. To respond to this, there is a known technique of suppressing a peak current by performing, for example, control to activate circuit blocks sequentially in time (see Japanese Patent No. 5580751 and Japanese Patent No. 6578413).

### CITATION LIST

### Patent Literature

PTL 1: Japanese Patent No. 5580751
PTL 2: Japanese Patent No. 6578413

### SUMMARY

### Technical Problem

When performing, for example, control to activate circuit blocks sequentially in time, there is a concern about complication of control or an increase in circuit areas, for example.

In view of this, the present disclosure aims to provide a semiconductor memory device and a control method that can suppress a peak current and complication of control or an increase in circuit areas resulting from the suppression of the peak current.

### Solution to Problem

A semiconductor memory device according to one aspect of the present disclosure includes: a plurality of memory cells; a first power supply line to which a power supply voltage is supplied; a second power supply line serving as the power supply voltage line of the plurality of memory cells; a first transistor and a second transistor that are connected in parallel between the first power supply line and the second power supply line; and a control circuit that, in accordance with a first signal for switching between a first mode and a second mode, (i) switches off the first transistor and the second transistor in the period of the second mode and (ii) switches on the first transistor when switching from the second mode to the first mode is performed and switches on the second transistor after the first transistor is switched on, the first mode being a mode for supplying the power supply voltage to the plurality of memory cells, the second mode being a mode for not supplying the power supply voltage to the plurality of memory cells.

A semiconductor memory device according to another aspect of the present disclosure includes: a plurality of memory cells; a first bit line connected to the plurality of memory cells; a first pre-charge circuit and a second pre-charge circuit that are connected to the first bit line; and a control circuit that, in accordance with a first signal for switching between a first mode and a second mode, (i) switches off the first pre-charge circuit and the second pre-charge circuit in the period of the second mode and (ii) switches on the first pre-charge circuit when switching from the second mode to the first mode is performed and switches on the second pre-charge circuit after the first pre-charge circuit is switched on, the first mode being a mode for pre-charging the first bit line, the second mode being a mode for not pre-charging the first bit line.

It should be noted that these general or specific aspects may be embodied as a system, a method, or an integrated circuit or may be embodied by any combination of the system, the method, and the integrated circuit.

### Advantageous Effects

The present disclosure can provide a semiconductor memory device and a control method that can suppress a peak current and complication of control or an increase in circuit areas resulting from the suppression of the peak current.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram of a semiconductor memory device according to Embodiment 1.

FIG. 2 illustrates configurations of a power supply control circuit and a memory cell array according to Embodiment 1.

FIG. 3 is a circuit diagram of a memory cell according to Embodiment 1.

FIG. 4 is a timing diagram related to the power supply control circuit according to Embodiment 1.

FIG. 5 illustrates a configuration of a variation of the power supply control circuit according to Embodiment 1.

FIG. 6 is a timing diagram related to the variation of the power supply control circuit according to Embodiment 1.

FIG. 7 is a block diagram of a semiconductor memory device according to Embodiment 2.

FIG. 8 illustrates a configuration of a write assist circuit according to Embodiment 2.

FIG. 9 illustrates a configuration of a column circuit according to Embodiment 2.

FIG. 10 is a timing diagram related to the write assist circuit according to Embodiment 2.

FIG. 11 is a block diagram of a semiconductor memory device according to Embodiment 3.

FIG. 12 illustrates a configuration of an input-output circuit according to Embodiment 3.

FIG. 13 is a timing diagram related to the input-output circuit according to Embodiment 3.

FIG. 14 illustrates a configuration of variation 1 of the input-output circuit according to Embodiment 3.

FIG. 15 is a timing diagram related to variation 1 of the input-output circuit according to Embodiment 3.

FIG. 16 illustrates a configuration of variation 2 of the input-output circuit according to Embodiment 3.

### DESCRIPTION OF EMBODIMENTS

A semiconductor memory device according to one aspect of the present disclosure includes: a plurality of memory cells; a first power supply line to which a power supply voltage is supplied; a second power supply line serving as the power supply voltage line of the plurality of memory cells; a first transistor and a second transistor that are connected in parallel between the first power supply line and the second power supply line; and a control circuit that, in accordance with a first signal for switching between a first mode and a second mode, (i) switches off the first transistor and the second transistor in the period of the second mode and (ii) switches on the first transistor when switching from the second mode to the first mode is performed and switches on the second transistor after the first transistor is switched on, the first mode being a mode for supplying the power supply voltage to the plurality of memory cells, the second mode being a mode for not supplying the power supply voltage to the plurality of memory cells.

Thus, in the semiconductor memory device, the first transistor is switched on when the operation mode is switched from the second mode to the first mode, and then the second transistor is switched on, which can suppress the peak current associated with power restoration. Furthermore, it is possible to suppress complication of control, compared with when blocks are controlled sequentially in time, for instance.

For instance, the second transistor may have a drive performance higher than the drive performance of the first transistor.

Thus, it is possible to suppress the peak current efficiently.

For instance, the control circuit may include a delay circuit that generates a second signal by delaying the first signal, the first signal may be supplied to the control terminal of the first transistor, and the second signal may be supplied to the control terminal of the second transistor.

Thus, it is possible to control the first transistor and the second transistor with a simple configuration.

For instance, the semiconductor memory device may further include a plurality of memory blocks each including the plurality of memory cells. The first transistor and the second transistor may be provided in each of the plurality of memory blocks, and the second signal generated by the delay circuit may be supplied to the control terminal of each of two or more second transistors provided in two or more of the plurality of memory blocks.

Thus, the two or more memory blocks can share the delay circuit, which results in reduction in circuit areas.

For instance, the control circuit may detect the voltage of the second power supply line, and after the first transistor is switched on when switching from the second mode to the first mode is performed, and when the voltage of the second power supply line reaches a predetermined voltage, the control circuit may switch on the second transistor.

Thus, it is possible to control the first transistor and the second transistor with high accuracy.

For instance, the semiconductor memory device may further include a write assist circuit that decreases, during data writing to the plurality of memory cells, the voltage of the second power supply line to a voltage lower than the voltage of the second power supply line at a time other than during the data writing. The write assist circuit may include the first transistor and the second transistor, and one of the first transistor or the second transistor may be off during the data writing.

Thus, since the first transistor and the second transistor can serve as the transistors used in the write assist circuit, it is possible to suppress the circuit areas from increasing.

For instance, a semiconductor memory device according to another aspect of the present disclosure includes a plurality of memory cells; a first bit line connected to the plurality of memory cells; a first pre-charge circuit and a second pre-charge circuit that are connected to the first bit line; and a control circuit that, in accordance with a first signal for switching between a first mode and a second mode, (i) switches off the first pre-charge circuit and the second pre-charge circuit in the period of the second mode and (ii) switches on the first pre-charge circuit when switching from the second mode to the first mode is performed and switches on the second pre-charge circuit after the first pre-charge circuit is switched on, the first mode being a mode for pre-charging the first bit line, the second mode being a mode for not pre-charging the first bit line.

Thus, in the semiconductor memory device, the first pre-charge circuit is switched on when the operation mode is switched from the second mode to the first mode, and then the second pre-charge circuit is switched on, which can suppress the peak current associated with power restoration. Furthermore, it is possible to suppress complication of control, compared with when blocks are controlled sequentially in time, for instance.

For instance, the second pre-charge circuit may have a drive performance higher than the drive performance of the first pre-charge circuit.

Thus, it is possible to suppress the peak current efficiently.

For instance, the control circuit may include a delay circuit that generates a second signal by delaying the first signal, the first pre-charge circuit may be switched between on and off in accordance with the first signal, and the second pre-charge circuit may be switched between on and off in accordance with the second signal.

Thus, it is possible to control the first pre-charge circuit and the second pre-charge circuit with a simple configuration.

For instance, the semiconductor memory device may further include: a plurality of memory blocks each including the plurality of memory cells. The first pre-charge circuit and the second pre-charge circuit may be provided in each of the plurality of memory blocks, and the second signal generated by the delay circuit may be supplied to two or more pre-charge circuits provided in two or more of the plurality of memory blocks.

Thus, the two or more memory blocks can share the delay circuit, which results in reduction in circuit areas.

For instance, the control circuit may detect the voltage of the first bit line, and after the first pre-charge circuit is switched on when switching from the second mode to the first mode is performed, and when the voltage of the first bit line reaches a predetermined voltage, the control circuit may switch on the second pre-charge circuit.

Thus, it is possible to control the first pre-charge circuit and the second pre-charge circuit with high accuracy.

For instance, the semiconductor memory device may further include: a second bit line connected to the plurality of memory cells. The first pre-charge circuit may include: a first transistor that includes a source and a drain, one of which is connected to the first bit line, and a gate connected to the second bit line; and a second transistor that includes a source and a drain, one of which is connected to the second bit line, and a gate connected to the first bit line.

Thus, the first pre-charge circuit can serve as a circuit for holding the voltages of the first bit line and the second bit line, which can suppress the circuit areas from increasing.

In addition, a control method according to still another aspect of the present disclosure is a method for controlling a semiconductor memory device that includes a plurality of memory cells, a first transistor, and a second transistor, the control method having a first mode for supplying a power supply voltage to the plurality of memory cells and a second mode for not supplying the power supply voltage to the plurality of memory cells. The control method includes: supplying the power supply voltage to the plurality of memory cells via the first transistor during a first period after switching from the second mode to the first mode is performed, and supplying the power supply voltage to the plurality of memory cells via the first transistor and the second transistor during a second period after the first period.

Thus, in the semiconductor memory device, the power supply voltage is supplied via the first transistor during the period after switching from the second mode to the first mode is performed, and then the power supply voltage is supplied via the first transistor and the second transistor, which can suppress the peak current associated with power restoration. Furthermore, it is possible to suppress complication of control, compared with when blocks are controlled sequentially in time, for instance.

In addition, a control method according to yet another aspect of the present disclosure is a method for controlling a semiconductor memory device that includes a plurality of memory cells, a bit line connected to the plurality of memory cells, a first pre-charge circuit, and a second pre-charge circuit, the control method having a first mode for pre-charging the bit line and a second mode for not pre-charging the bit line. The control method includes: pre-charging the bit line by the first pre-charge circuit during a first period after switching from the second mode to the first mode is performed, and pre-charging the bit line by the first pre-charge circuit and the second pre-charge circuit during a second period after the first period.

Thus, in the semiconductor memory device, the first pre-charge circuit pre-charges the bit line during the period after switching from the second mode to the first mode is performed, and then the first pre-charge circuit and the second pre-charge circuit pre-charge the bit line. In this way, it is possible to suppress the peak current associated with power restoration. Furthermore, it is possible to suppress complication of control, compared with when blocks are controlled sequentially in time, for instance.

It should be noted that these general or specific aspects may be embodied as a system, a method, or an integrated circuit or may be embodied by any combination of the system, the method, and the integrated circuit.

Embodiments are described below in detail with reference to the drawings. It should be noted that the embodiments described below each indicate a specific example of the present disclosure. The numerical values, shapes, materials, structural elements, arrangement and connection of the structural elements, steps, order of steps, and other details are mere examples and do not intend to limit the present disclosure. Among the structural elements described in the embodiments below, those not recited in the independent claims are described as optional structural elements.

### Embodiment 1

In Embodiment 1, a semiconductor memory device that suppresses a peak current when the operation mode returns from a power-down mode to a normal mode. Here, the peak current is defined as the maximum value of an instantaneous current. Furthermore, power supply noise occurs due to the increased peak current, which increases the possibility of causing a malfunction in, for example, other logic circuits.

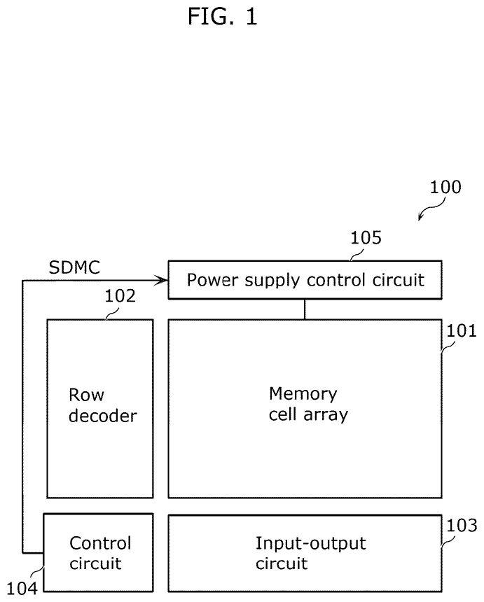

FIG. 1 is a block diagram of semiconductor memory device 100 according to Embodiment 1. Semiconductor memory device 100 is SRAM and includes memory cell array 101, row decoder 102, input-output circuit 103, control circuit 104, and power supply control circuit 105.

It should be noted that an example in which semiconductor memory device 100 is SRAM is described here. However, semiconductor memory device 100 may be other random access memory (RAM) such as dynamic random access memory (DRAM). Furthermore, semiconductor memory device 100 may be nonvolatile memory such as flash memory.

Furthermore, semiconductor memory device 100 is embodied as, for example, a large-scale integrated circuit (LSI), which is an integrated circuit. Integrated circuits may be made as individual chips, or some or all of the integrated circuits may be incorporated into one chip. Furthermore, semiconductor memory device 100 may be one block included in an LSI.

Memory cell array 101 includes memory cells 112 arranged in a matrix and each holding one-bit data. Row decoder 102 selects one of the rows of memory cells 112 arranged in a matrix. Input-output circuit 103 writes data to memory cell array 101 and reads out the data held by memory cell array 101.

Power supply control circuit 105 switches between supplying a power supply voltage (hereinafter, also referred to as supplying power) to memory cell array 101 and not supplying the power supply voltage to memory cell array 101.

Here, semiconductor memory device 100 has at least a power-down mode (a second mode) for not supplying power to memory cell array 101 and a normal mode (a first mode) for supplying power to memory cell array 101. It should be noted that in the power-down mode, power need not be supplied to peripheral circuits, such as row decoder 102 and input-output circuit 103. Furthermore, in the normal mode, power is supplied not only to memory cell array 101 but also to the peripheral circuits. It should be noted that semiconductor memory device 100 may further have a mode in which power is supplied to memory cell array 101 but not supplied to the peripheral circuits (a mode in which power is not supplied to the peripheral circuits but memory cell array 101 continues to hold data).

Control circuit 104 controls each processing unit. Specifically, control circuit 104 generates control signals for controlling the respective processing units. Furthermore, control circuit 104 generates signal SDMC for switching between the power-down mode and the normal mode, and supplies generated signal SDMC to power supply control circuit 105. For instance, control circuit 104 generates signal SDMC in accordance with a signal input from outside semiconductor memory device 100. It should be noted that control circuit 104 may supply, without any change, signal SDMC input from outside semiconductor memory device 100 to power supply control circuit 105. Alternatively, signal SDMC input from outside semiconductor memory device 100 may be directly supplied to power supply control circuit 105 without via control circuit 104.

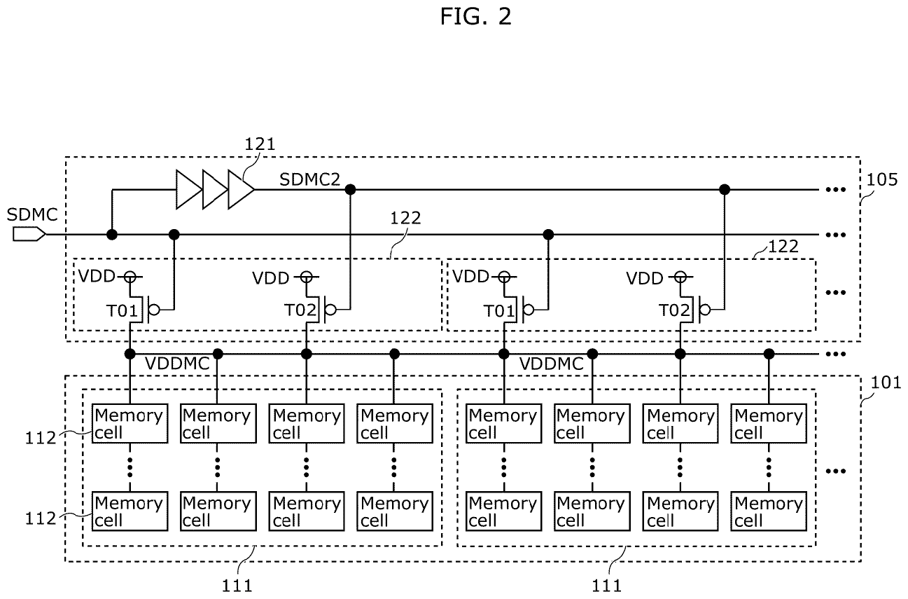

FIG. 2 illustrates configurations of memory cell array 101 and power supply control circuit 105. Memory cell array 101 includes memory blocks 111. Each memory block 111 includes memory cells 112. It should be noted that here, memory cell array 101 is horizontally divided for every plurality of columns, thereby forming memory blocks 111. However, memory blocks 111 may be formed by vertically dividing memory cell array 101 for every plurality of rows or by both horizontally and vertically dividing memory cell array 101 for every plurality of columns and for every plurality of rows. Furthermore, the number of memory cells 112 included in memory block 111 may be any number. Furthermore, memory cell array 101 need not be divided into memory blocks 111.

Each memory cell 112 is connected to memory power supply line VDDMC, which is the power supply line of memory cell 112. A power supply voltage is supplied to each memory cell 112 via memory power supply line VDDMC.

Power supply control circuit 105 includes delay circuit 121 and power supply switching circuits 122. Delay circuit 121 generates signal SDMC2 by delaying signal SDMC.

Power supply switching circuit 122 is provided for each memory block 111 and switches between supplying and not supplying power to memory cell array 101.

Power supply switching circuit 122 includes first transistor T01 and second transistor T02. First transistor T01 is connected between power supply line VDD to which a power supply voltage is supplied, and memory power supply line VDDMC. Specifically, the source of first transistor T01 is connected to power supply line VDD, and the drain of first transistor T01 is connected to memory power supply line VDDMC. Signal SDMC is supplied to the gate (control terminal) of first transistor T01. It should be noted that power supply line VDD is the power supply line of semiconductor memory device 100, and, for instance, a power supply voltage supplied from outside semiconductor memory device 100 is applied to power supply line VDD.

Second transistor T02 is connected between power supply line VDD and memory power supply line VDDMC. Specifically, the source of second transistor T02 is connected to power supply line VDD, and the drain of second transistor T02 is connected to memory power supply line VDDMC. Signal SDMC2 is supplied to the gate (control terminal) of second transistor T02. That is, first transistor T01 and second transistor T02 are connected in parallel between power supply line VDD and memory power supply line VDDMC.

Furthermore, second transistor T02 has a drive performance higher than that of first transistor T01. Here, the high and low levels of drive performance are adjusted by, for example, gate width/gate length (W/L) of a transistor, the threshold voltage of the transistor, or the level of a voltage applied to the gate or source of the transistor. It should be noted that the drive performance of second transistor T02 may be the same as or lower than that of first transistor T01.

It should be noted that in Embodiment 1, an example in which a metal-oxide-semiconductor field-effect transistor (MOSFET) is mainly used as a transistor is provided. However, other transistors such as a bipolar transistor may be used.

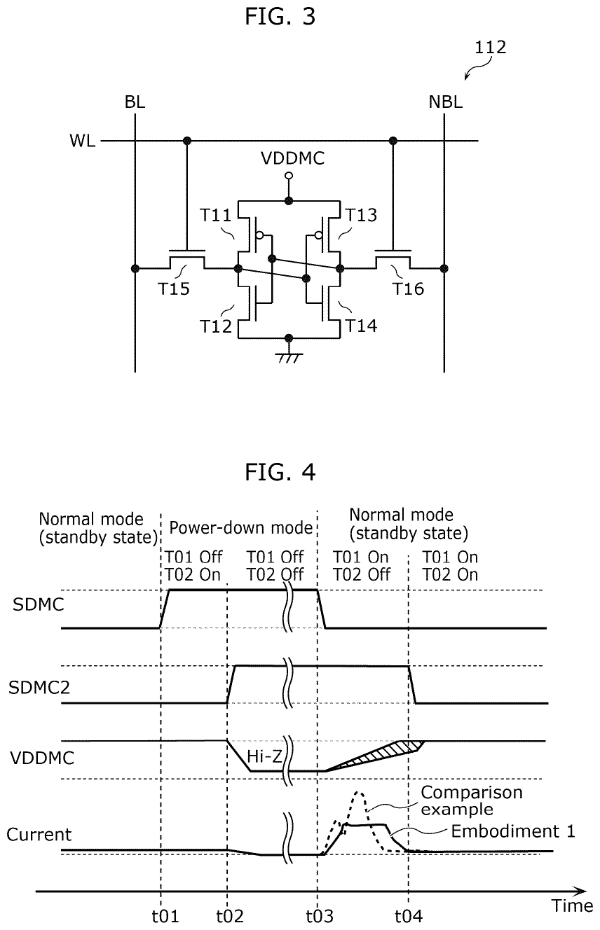

FIG. 3 is a circuit diagram of memory cell 112. As illustrated in FIG. 3, memory cell 112 is, for example, a SRAM memory cell including six transistors T11 to T16, and is connected to word line WL provided for each row and connected to a pair of bit line BL and bit line NBL provided for each column. Furthermore, a power supply voltage is supplied to memory cell 112 via memory power supply line VDDMC.

Then, an operation of semiconductor memory device 100 of the above configuration performed when switching the operation modes is described. FIG. 4 is a timing diagram illustrating an operation of semiconductor memory device 100 performed when switching the operation modes. Signal SDMC is at a low level during the normal mode and at a high level during the power-down mode.

In the period before time t01 illustrated in FIG. 4, signal SDMC is at the low level, and semiconductor memory device 100 is operating in the normal mode. It should be noted that in the normal mode, the state in which a writing operation and a readout operation are not being performed is referred to as a standby state.

At time t01, signal SDMC changes from the low level to the high level, and the operation mode transitions to the power-down mode. When signal SDMC reaches the high level, first transistor T01 is switched off. Furthermore, signal SDMC2 changes to the high level at time t02 later than signal SDMC. When signal SDMC2 reaches the high level, second transistor T02 is switched off. When both first transistor T01 and second transistor T02 are switched off, power supply to memory cell array 101 is cut off, and memory power supply line VDDMC becomes a high-impedance (Hi-Z) state.

At time t03, signal SDMC changes from the high level to the low level, and the operation mode transitions from the power-down mode to the normal mode. When signal SDMC reaches the low level, first transistor T01 is switched on. Thus, power supply to memory power supply line VDDMC is started, and the voltage of memory power supply line VDDMC starts increasing.

Furthermore, signal SDMC2 changes to the low level at time t04 later than signal SDMC. When signal SDMC2 reaches the low level, second transistor T02 is switched on.

Thus, in the period from time t03 to time t04 after the operation mode is switched from the power-down mode to the normal mode, first transistor T01 is switched on, whereas second transistor T02 is not switched on. This can suppress the peak current when switching the operation modes. Furthermore, during the period after time t04, both first transistor T01 and second transistor T02 are on, which enables power supply at a sufficient level.

It should be noted that in FIG. 4, the current indicated by the solid line is a current when a method in Embodiment 1 is applied, and the current indicated by the dashed line is a current (in a comparison example) when the method in Embodiment 1 is not applied. Furthermore, the hatched portion in the period from time t03 to time t04 in memory power supply line VDDMC, illustrated in FIG. 4 indicates voltage value variations based on, for example, operation states and manufacturing variations.

As described above, semiconductor memory device 100 according to Embodiment 1 includes memory cells 112, first power supply line VDD to which a power supply voltage is supplied, second power supply line VDDMC serving as the power supply voltage line of memory cells 112, first transistor T01 and second transistor T02 that are connected in parallel between first power supply line VDD and second power supply line VDDMC, and control circuit 105. In accordance with first signal SDMC for switching between the first mode (the normal mode) and the second mode (the power-down mode), control circuit 105 (i) switches off first transistor T01 and second transistor T02 in the period of the second mode and (ii) switches on first transistor T01 when switching from the second mode to the first mode is performed and switches on second transistor T02 after first transistor T01 is switched on, the first mode being a mode for supplying the power supply voltage to memory cells 112, the second mode being a mode for not supplying the power supply voltage to memory cells 112.

Thus, in semiconductor memory device 100, first transistor T01 is switched on when the operation mode is switched from the second mode to the first mode, and then second transistor T02 is switched on, which can suppress the peak current associated with power restoration. Furthermore, it is possible to suppress complication of control, compared with when blocks are controlled sequentially in time, for instance.

For instance, second transistor T02 has a drive performance higher than that of first transistor T01. Thus, it is possible to suppress the peak current efficiently.

For instance, power supply control circuit 105 includes delay circuit 121 that generates second signal SDMC2 by delaying first signal SDMC. First signal SDMC is supplied to the control terminal of first transistor T01, and second signal SDMC2 is supplied to the control terminal of second transistor T02. Thus, it is possible to control first transistor T01 and second transistor T02 with a simple configuration.

For instance, semiconductor memory device 100 includes memory blocks 111 each including memory cells 112. First transistor T01 and second transistor T02 are provided in each of memory blocks 111. Second signal SDMC2 generated by delay circuit 121 is supplied to the control terminal of each of two or more second transistors T02 provided in two or more of memory blocks 111. Thus, two or more memory blocks 111 can share delay circuit 121, which results in reduction in circuit areas.

It should be noted that FIG. 2 illustrates an example in which signal SDMC2 generated by delay circuit 121 is supplied to all second transistors T02 (that is, an example in which all second transistors T02 share one delay circuit 121). However, delay circuit 121 may be provided for each memory block 111 or for every plurality of memory blocks 111 (for each second transistor T02 or for every plurality of second transistors T02), and signal SDMC2 generated by each delay circuit 121 may be supplied to corresponding second transistor T02 or corresponding second transistors T02.

Furthermore, a control method for controlling semiconductor memory device 100 according to Embodiment 1 is a control method for controlling semiconductor memory device 100 that includes memory cells 112, first transistor T01, and second transistor T02. The control method has the first mode (the normal mode) for supplying a power supply voltage to memory cells 112 and the second mode (the power-down mode) for not supplying the power supply voltage to memory cells 112. In the control method, during a first period (from t03 to t04 in FIG. 4) after the operation mode is switched from the second mode to the first mode, a power supply voltage is supplied to memory cells 112 via first transistor T01. During a second period (the period after t04 in FIG. 4), the power supply voltage is supplied to memory cells 112 via first transistor T01 and second transistor T02.

Thus, in semiconductor memory device 100, during the period after the operation mode is switched from the second mode to the first mode, the power supply voltage is supplied via first transistor T01, and then the power supply voltage is supplied via first transistor T01 and second transistor T02, which can suppress the peak current associated with power restoration. Furthermore, it is possible to suppress complication of control, compared with when blocks are controlled sequentially in time, for instance.

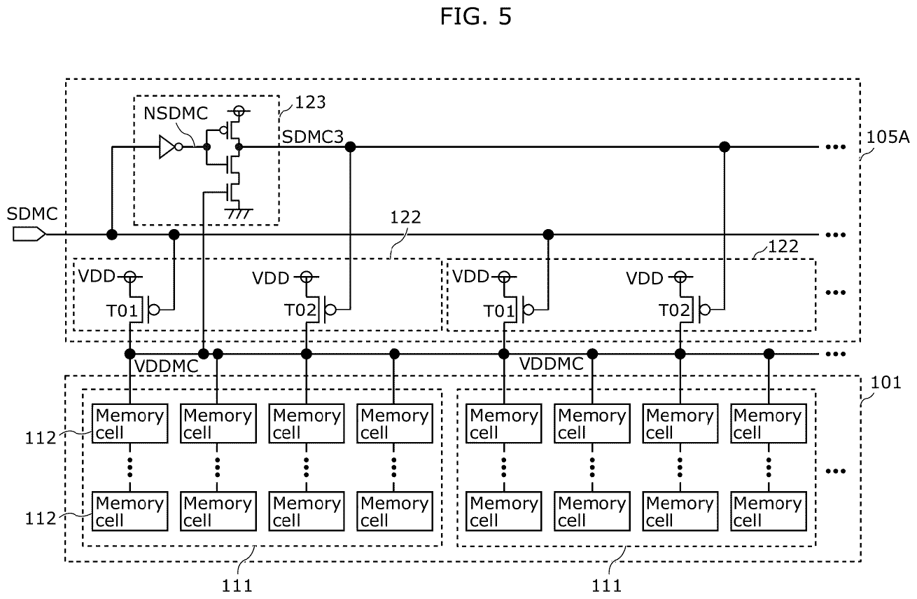

A variation of power supply control circuit 105 is described below. FIG. 5 illustrates a configuration of power supply control circuit 105A, which is a variation of power supply control circuit 105. Power supply control circuit 105A in FIG. 5 includes voltage detection circuit 123 instead of delay circuit 121. In this respect, power supply control circuit 105A differs from power supply control circuit 105 in FIG. 2.

Voltage detection circuit 123 detects the voltage of memory power supply line VDDMC. Voltage detection circuit 123 generates signal SDMC3 that changes to a low level when signal SDMC is at a low level (the normal mode) and the voltage of memory power supply line VDDMC is greater than or equal to a predetermined voltage, and changes to a high level under the other conditions. Signal SDMC3 is supplied to the gate (control terminal) of second transistor T02. It should be noted that the circuit configuration of voltage detection circuit 123 in FIG. 5 is an example, and any circuit configuration may be applied as long as a similar function can be achieved.

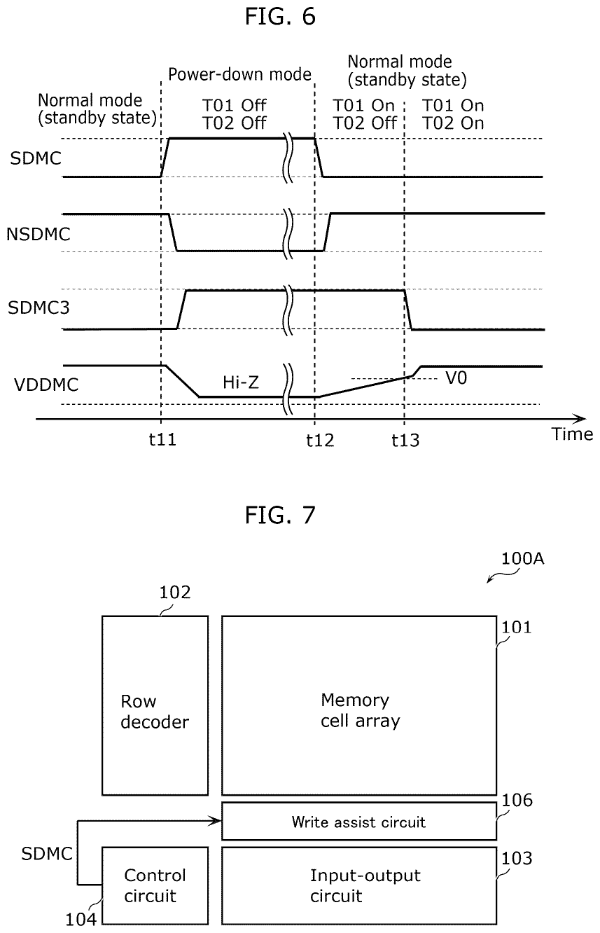

FIG. 6 is a timing diagram illustrating an operation performed when switching the operation modes, in the variation of power supply control circuit 105. In the period before time t11 illustrated in FIG. 6, signal SDMC is at a low level, and semiconductor memory device 100 is operating in the normal mode.

At time t11, signal SDMC changes from the low level to a high level, and the operation mode transitions to the power-down mode. When signal SDMC reaches the high level, first transistor T01 is switched off. Furthermore, when signal SDMC reaches the high level, signal SDMC3 reaches the high level. When signal SDMC3 reaches the high level, second transistor T02 is switched off. When both first transistor T01 and second transistor T02 are switched off, power supply to memory cell array 101 is cut off, and memory power supply line VDDMC becomes the Hi-Z state.

At time t12, signal SDMC changes from the high level to the low level, and the operation mode transitions from the power-down mode to the normal mode. When signal SDMC reaches the low level, first transistor T01 is switched on.

When first transistor T01 is switched on, the voltage of memory power supply line VDDMC increases, and the voltage reaches predetermined voltage V0 at time t13. Voltage detection circuit 123 detects that the voltage of memory power supply line VDDMC has reached voltage V0, and changes signal SDMC3 to the low level. When signal SDMC3 reaches the low level, second transistor T02 is switched on.

Thus, in the period from time t12 to time t13 after the operation mode is switched from the power-down mode to the normal mode, first transistor T01 is switched on, whereas second transistor T02 is not switched on. This can suppress the peak current when switching the operation modes. Furthermore, during the period after time t13, both first transistor T01 and second transistor T02 are on, which enables power supply at a sufficient level.

As described above, power supply control circuit 105A detects the voltage of second power supply line VDDMC. After first transistor T01 is switched on when the operation mode is switched from the second mode (the power-down mode) to the first mode (the normal mode), and when the voltage of second power supply line VDDMC reaches predetermined voltage V0, power supply control circuit 105A switches on second transistor T02. Thus, it is possible to control first transistor T01 and second transistor T02 with high accuracy.

### Embodiment 2

In Embodiment 2, an example in which a write assist circuit also has the function of power supply control circuit 105 described in Embodiment 1 is described. The write assist circuit controls the power supply voltage of memory cell array 101 during data writing.

FIG. 7 is a block diagram of semiconductor memory device 100A according to Embodiment 2. Semiconductor memory device 100A in FIG. 7 includes write assist circuit 106 instead of power supply control circuit 105 included in semiconductor memory device 100 in FIG. 1.

Write assist circuit 106 is a circuit for facilitating data writing by decreasing the power supply voltage of memory cell 112 during the data writing. In Embodiment 2, write assist circuit 106 has the function of power supply control circuit 105 described in Embodiment 1.

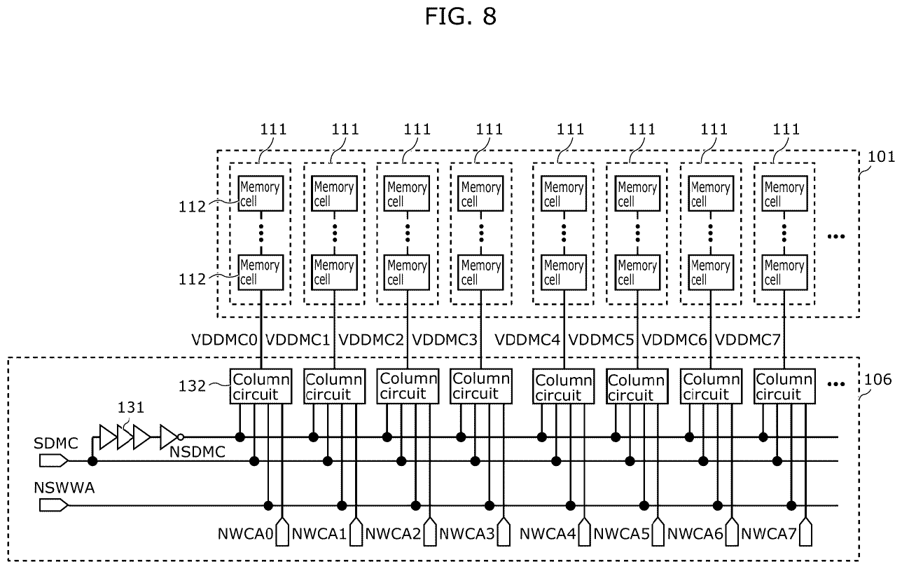

FIG. 8 illustrates configurations of memory cell array 101 and write assist circuit 106. Memory cell array 101 includes memory blocks 111. Each memory block 111 includes memory cells 112. It should be noted that here, memory cell array 101 is divided for each column into memory blocks 111.

Furthermore, memory power supply line VDDMC (a corresponding one of VDDMC0 to VDDMC7) is provided for each column (for each memory block 111). Each memory block 111 is connected to corresponding memory power supply line VDDMC, and a power supply voltage is supplied to each memory block 111 via corresponding memory power supply line VDDMC.

Write assist circuit 106 includes delay circuit 131 and column circuits 132. Delay circuit 131 generates signal NSDMC by delaying and inverting signal SDMC.

Column circuit 132 is provided for each column and controls the level of the power supply voltage to be supplied to memory cells 112 in the column. Specifically, column circuit 132 performs control to decrease the power supply voltage during data writing. Furthermore, when the operation modes are switched, column circuit 132 performs control similar to the control explained in Embodiment 1.

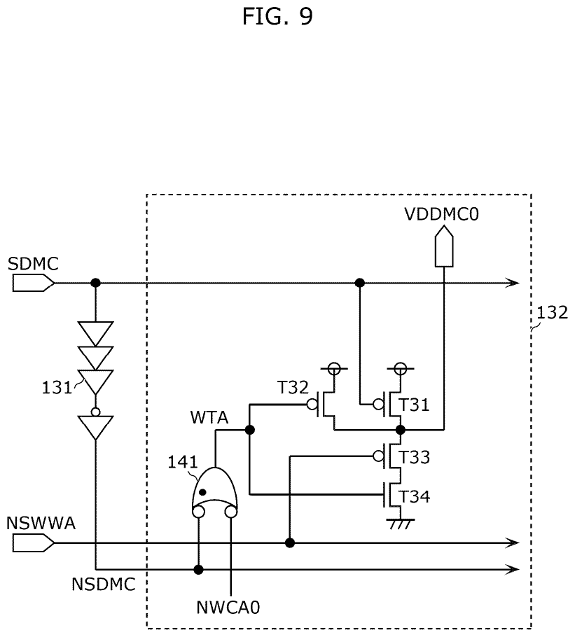

FIG. 9 illustrates a configuration of column circuit 132. As illustrated in FIG. 9, column circuit 132 includes logic circuit 141 and transistors T31 to T34.

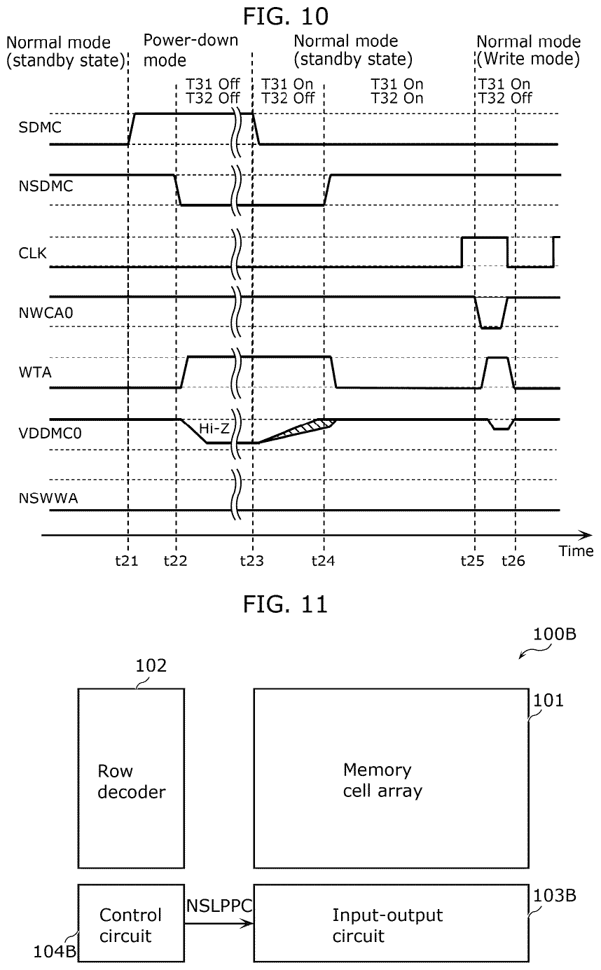

FIG. 10 is a timing diagram illustrating an operation performed when switching the operation modes in Embodiment 2. Signal SDMC is at a low level during a normal mode and at a high level during a power-down mode. Signal NSWWA indicates whether write assistance is provided. When write assistance is provided, signal NSWWA is at the low level, and when write assistance is not provided, signal NSWWA is at the high level. In FIG. 10, signal NSWWA is at the low level, and write assistance is provided.

Signal NWCA (each of NWCA0 to NWCA7) is a signal indicating whether the mode is a write mode for writing data to memory cell 112. Signal NWCA is at the low level during the write mode, and signal NWCA is at the high level at times other than during the write mode. Furthermore, signal CLK illustrated in FIG. 10 is a clock signal for use in a write operation. Signal NSWWA, signal NWCA, and signal CLK are generated by, for example, control circuit 104. It should be noted that control circuit 104 may generate at least one of the signals in accordance with a signal input from outside semiconductor memory device 100A. Furthermore, control circuit 104 may supply, without any change, the signal input from outside semiconductor memory device 100A to write assist circuit 106. Alternatively, the signal input from outside semiconductor memory device 100A may be directly supplied to write assist circuit 106 without via control circuit 104.

Logic circuit 141 generates signal WTA in accordance with signal NSDMC and signal NWCA0. Specifically, when at least one of signal NSDMC or signal NWCA0 is at the low level, logic circuit 141 outputs high-level signal WTA. Otherwise, logic circuit 141 outputs low-level signal WTA.

First transistor T31 corresponds to first transistor T01 according to Embodiment 1. First transistor T31 is connected between power supply line VDD to which a power supply voltage is supplied, and memory power supply line VDDMC0. Specifically, the source of first transistor T31 is connected to power supply line VDD, and the drain of first transistor T31 is connected to memory power supply line VDDMC0. Signal SDMC is supplied to the gate (control terminal) of first transistor T31.

Second transistor T32 is connected between power supply line VDD and memory power supply line VDDMC0. Specifically, the source of second transistor T32 is connected to power supply line VDD, and the drain of second transistor T32 is connected to memory power supply line VDDMC0. Signal WTA is supplied to the gate (control terminal) of second transistor T32. That is, first transistor T31 and second transistor T32 are connected in parallel between power supply line VDD and memory power supply line VDDMC0.

Furthermore, second transistor T32 has a drive performance higher than that of first transistor T31. It should be noted that the drive performance of second transistor T32 may be the same as or lower than that of first transistor T31.

Transistor T33 and transistor T34 are connected in series between memory power supply line VDDMC0 and a ground line to which a ground potential is supplied. Signal NSWWA is supplied to the gate (control terminal) of transistor T33. Signal WTA is supplied to the gate (control terminal) of transistor T34.

In the period before time t21 illustrated in FIG. 10, signal SDMC is at the low level, and semiconductor memory device 100 is operating in the normal mode.

At time t21, signal SDMC changes from the low level to the high level, and the operation mode transitions to the power-down mode. When signal SDMC reaches the high level, first transistor T31 is switched off. Furthermore, signal NSDMC changes to the low level at time t22 later than signal SDMC changes to the high level, and signal WTA changes to the high level. When signal WTA reaches the high level, second transistor T32 is switched off. When both first transistor T31 and second transistor T32 are switched off, power supply to memory cell array 101 is cut off, and memory power supply line VDDMC0 becomes the Hi-Z state.

At time t23, signal SDMC changes from the high level to the low level, and the operation mode transitions from the power-down mode to the normal mode. When signal SDMC reaches the low level, first transistor T31 is switched on. Thus, power supply to memory power supply line VDDMC0 is started, and the voltage of memory power supply line VDDMC0 starts increasing.

Furthermore, signal NSDMC changes to the high level at time t24 later than signal SDMC changes to the low level, and signal WTA changes to the low level. When signal WTA reaches the low level, second transistor T32 is switched on.

Thus, in the period from time t23 to time t24 after the operation mode is switched from the power-down mode to the normal mode, first transistor T31 is switched on, whereas second transistor T32 is not switched on. This can suppress the peak current when switching the operation modes. Furthermore, during the period after time t24, both first transistor T31 and second transistor T32 are on, which enables power supply at a sufficient level.

Furthermore, signal NWCA0 changes to the low level at time t25, and the operation mode transitions to the write mode. When signal NWCA0 reaches the low level, signal WTA reaches the high level. Thus, second transistor T32 is switched off, and transistor T34 is switched on. Furthermore, as signal NSWWA is at the low level, transistor T33 is in an on-state. As signal SDMC is at the low level, first transistor T31 is in an on-state. Thus, the voltage of memory power supply line VDDMC0 becomes a voltage corresponding to the ratio of the on-resistance of first transistor T31 to the on-resistance of transistors T33 and T34. That is, the voltage of memory power supply line VDDMC0 decreases, which enables write assistance.

As described above, semiconductor memory device 100A according to Embodiment 2 includes write assist circuit 106 that decreases, during the data writing to memory cells 112, the voltage of second power supply line VDDMC0 to a voltage lower than the voltage of second power supply line VDDMC0 at a time other than during the data writing. Write assist circuit 106 includes first transistor T31 and second transistor T32. One of first transistor T31 or second transistor T32 is off during data writing. Thus, since first transistor T31 and second transistor T32 can serve as the transistors used in write assist circuit 106, it is possible to suppress circuit areas from increasing.

### Embodiment 3

In Embodiments 1 and 2, the methods of decreasing the peak current when power is restored to memory cell 112 are described. In Embodiment 3, an example in which a similar method is applied to a circuit for pre-charging a bit line is described.

FIG. 11 is a block diagram of semiconductor memory device 100B according to Embodiment 3. Semiconductor memory device 100B in FIG. 11 does not include power supply control circuit 105 that is included in semiconductor memory device 100 in FIG. 1. The configurations of input-output circuit 103B and control circuit 104B differ from those of input-output circuit 103 and control circuit 104.

Furthermore, semiconductor memory device 100B has a power-down mode (a second mode) for not pre-charging a bit line and a normal mode (a first mode) for pre-charging the bit line. It should be noted that in the power-down mode, power need not be supplied to the circuits other than pre-charge related circuits included in row decoder 102 and input-output circuit 103B. Furthermore, in the normal mode, power is also supplied to the circuits other than the pre-charge related circuits. It should be noted that in the power-down mode, power may be supplied to or need not be supplied to memory cell array 101. It should be noted that in a state in which power is not supplied to peripheral circuits, semiconductor memory device 100B may have a mode for supplying power to memory cell array 101 and a mode for not supplying power to memory cell array 101.

Control circuit 104B generates signal NSLPPC for switching between the power-down mode and the normal mode, and supplies generated signal NSLPPC to input-output circuit 103B. For instance, control circuit 104B generates signal NSLPPC in accordance with a signal input from outside semiconductor memory device 100B. It should be noted that control circuit 104B may supply, without any change, signal NSLPPC input from outside semiconductor memory device 100B to input-output circuit 103B. Alternatively, signal NSLPPC input from outside semiconductor memory device 100B may be directly supplied to input-output circuit 103B without via control circuit 104B.

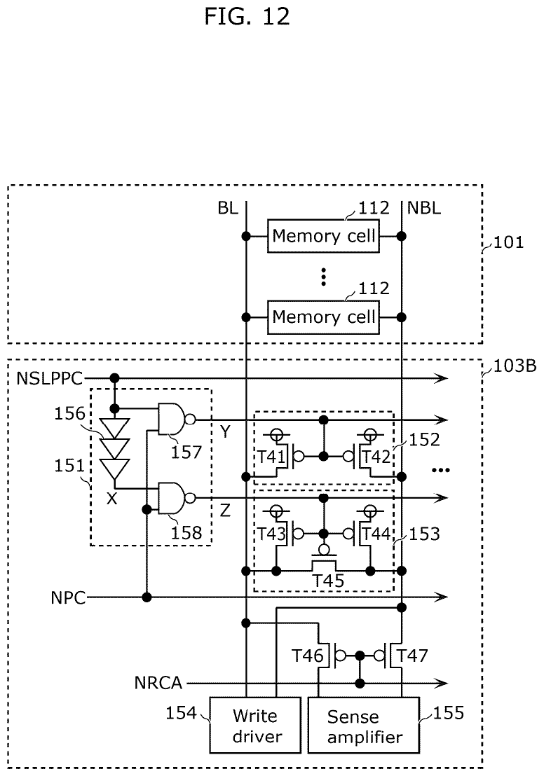

FIG. 12 illustrates configurations of memory cell array 101 and input-output circuit 103B. It should be noted that FIG. 12 illustrates a circuit configuration corresponding to one column of memory cell array 101, and the configuration illustrated in FIG. 12 is provided for each column. It should be noted that pre-charge control circuit 151 included in the configuration illustrated in FIG. 12 may be provided as a common circuit shared by a plurality of columns.

Memory cells 112 are connected to a pair of bit line BL and bit line NBL provided for each column.

Input-output circuit 103B includes pre-charge control circuit 151, first pre-charge circuit 152, second pre-charge circuit 153, write driver 154, sense amplifier 155, transistor T46, and transistor T47.

In accordance with signal NSLPPC and signal NPC, pre-charge control circuit 151 generates signal Y for controlling on and off of first pre-charge circuit 152 and signal Z for controlling on and off of second pre-charge circuit 153. Pre-charge control circuit 151 includes delay circuit 156, logic circuit 157, and logic circuit 158.

Signal NSLPPC is at a high level during the normal mode and at a low level during the power-down mode. Signal NPC is a signal indicating whether pre-charging is performed. When pre-charging performed (during the standby operation), signal NPC is at the high level, and when pre-charging is not performed (during data read out and writing), signal NPC is at the low level. Signal NRCA is an address selection signal. During readout, signal NRCA is at the low level. Otherwise, signal NRCA is at the high level.

Delay circuit 156 generates signal X by delaying signal NSLPPC. Logic circuit 157 is a NAND circuit. When at least one of signal NSLPPC or signal NPC is at the low level, logic circuit 157 outputs high-level signal Y. Otherwise, logic circuit 157 outputs low-level signal Y. Logic circuit 158 is a NAND circuit. When at least one of signal X or signal NPC is at the low level, logic circuit 158 outputs high-level signal Z. Otherwise, logic circuit 158 outputs low-level signal Z.

First pre-charge circuit 152 is a circuit for pre-charging bit line BL and bit line NBL. When signal Y is at the low level, first pre-charge circuit 152 pre-charges bit line BL and bit line NBL. When signal Y is at the high level, first pre-charge circuit 152 does not pre-charge bit line BL or bit line NBL. First pre-charge circuit 152 includes transistors T41 and T42.

Transistor T41 is connected between power supply line VDD to which a power supply voltage is supplied, and bit line BL. Specifically, the source of transistor T41 is connected to power supply line VDD, and the drain of transistor T41 is connected to bit line BL. Signal Y is supplied to the gate (control terminal) of transistor T41. It should be noted that power supply line VDD is the power supply line of semiconductor memory device 100B, and, for instance, a power supply voltage supplied from outside semiconductor memory device 100B is applied to power supply line VDD.

Transistor T42 is connected between power supply line VDD and bit line NBL. Specifically, the source of transistor T42 is connected to power supply line VDD, and the drain of transistor T42 is connected to bit line NBL. Signal Y is supplied to the gate (control terminal) of transistor T42.

Second pre-charge circuit 153 is a circuit for pre-charging bit line BL and bit line NBL. When signal Z is at the low level, second pre-charge circuit 153 pre-charges bit line BL and bit line NBL. When signal Z is at the high level, second pre-charge circuit 153 does not pre-charge bit line BL or bit line NBL. Second pre-charge circuit 153 includes transistors T43, T44, and T45.

Transistor T43 is connected between power supply line VDD and bit line BL. Specifically, the source of transistor T43 is connected to power supply line VDD, and the drain of transistor T43 is connected to bit line BL. Signal Z is supplied to the gate (control terminal) of transistor T43. That is, transistor T41 and transistor T43 are connected in parallel between power supply line VDD and bit line BL.

Transistor T44 is connected between power supply line VDD and bit line NBL. Specifically, the source of transistor T44 is connected to power supply line VDD, and the drain of transistor T44 is connected to bit line NBL. Signal Z is supplied to the gate (control terminal) of transistor T44. That is, transistor T42 and transistor T44 are connected in parallel between power supply line VDD and bit line NBL.

Transistor T45 is connected between bit line BL and bit line NBL. Signal Z is supplied to the gate (control terminal) of transistor T45.

Furthermore, transistors T43 and T44 have drive performances higher than those of transistors T41 and T42. Here, the high and low levels of drive performance are adjusted by, for example, gate width/gate length (W/L) of a transistor, the threshold voltage of the transistor, or the level of a voltage applied to the gate or source of the transistor. It should be noted that the drive performances of transistors T43 and T44 may be the same as or lower than those of transistors T41 and T42.

During writing, write driver 154 drives bit line BL and bit line NBL according to the write data. Sense amplifier 155 detects the voltages of bit line BL and bit line NBL during readout and generates readout data corresponding to the detected voltages. Transistor T46 is connected between bit line BL and sense amplifier 155, and transistor T47 is connected between bit line NBL and sense amplifier 155.

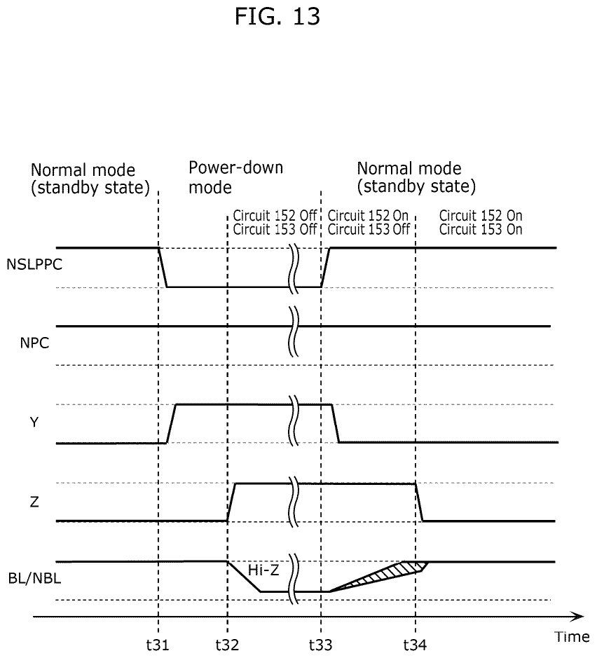

Then, an operation of semiconductor memory device 100B of the above configuration performed when switching the operation modes is described. FIG. 13 is a timing diagram illustrating an operation of semiconductor memory device 100B performed when switching the operation modes.

During the period before time t31 illustrated in FIG. 13, signal NSLPPC is at a high level, and semiconductor memory device 100B is operating in the normal mode. At time t31, signal NSLPPC changes from the high level to a low level, and the operation mode transitions to the power-down mode. When signal NSLPPC reaches the low level, signal Y reaches the high level. Thus, first pre-charge circuit 152 is switched off. That is, transistors T41 and T42 are switched off.

Furthermore, signal Z changes to the high level at time t32 later than signal Y. When signal Z reaches the high level, second pre-charge circuit 153 is switched off. That is, transistors T43, T44, and T45 are switched off.

When both first pre-charge circuit 152 and second pre-charge circuit 153 are switched off, bit line BL and bit line NBL are not pre-charged and become the Hi-Z state.

At time t33, signal NSLPPC changes from the low level to the high level, and the operation mode transitions from the power-down mode to the normal mode. When signal NSLPPC reaches the high level, signal Y reaches the low level. Thus, first pre-charge circuit 152 is switched on. That is, transistors T41 and T42 are switched on. Thus, power supply to (pre-charging of) bit line BL and bit line NBL is started, and the voltages of bit line BL and bit line NBL start increasing.

Furthermore, signal Z changes to the low level at time t34 later than signal Y. When signal Z reaches the low level, second pre-charge circuit 153 is switched on. That is, transistors T43, T44, and T45 are switched on.

Thus, in the period from time t33 to time t34 after the operation mode is switched from the power-down mode to the normal mode, first pre-charge circuit 152 is switched on, and second pre-charge circuit 153 is not switched on. This can suppress the peak current when switching the operation modes. Furthermore, during the period after time t34, both first pre-charge circuit 152 and second pre-charge circuit 153 are on, which enables voltage supply at a sufficient level.

Variation 1 of input-output circuit 103B is described below. In the above configuration, the pre-charge circuits are switched between on and off by controlling the gates of the transistors included in the pre-charge circuits. In variation 1 of input-output circuit 103B, a pre-charge circuit is switched between on and off, by switching between supplying and not supplying a power supply voltage to the pre-charge circuit.

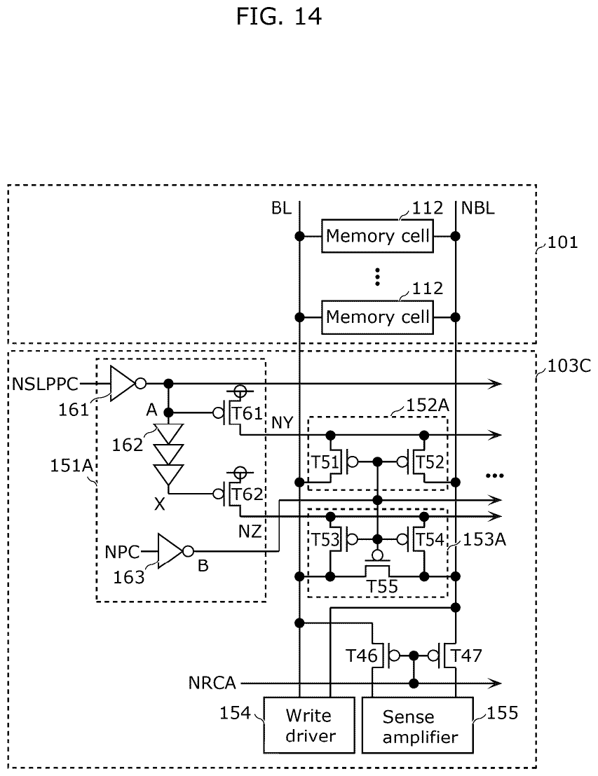

FIG. 14 illustrates a configuration of input-output circuit 103C, which is a variation of input-output circuit 103B. Input-output circuit 103C differs from input-output circuit 103B in the following point: configurations of pre-charge control circuit 151A, first pre-charge circuit 152A, and second pre-charge circuit 153A differ from those of pre-charge control circuit 151, first pre-charge circuit 152, and second pre-charge circuit 153.

It should be noted that pre-charge control circuit 151A included in the configuration illustrated in FIG. 14 may be provided as a common circuit shared by a plurality of columns.

In accordance with signal NSLPPC, pre-charge control circuit 151A generates signal NY for controlling on and off of first pre-charge circuit 152A and signal NZ for controlling on and off of second pre-charge circuit 153A. Pre-charge control circuit 151A includes inverters 161 and 163, delay circuit 162, and transistors T61 and T62.

Inverter 161 generates signal A by inverting signal NSLPPC. Delay circuit 162 generates signal X by delaying signal A. Inverter 163 generates signal B by inverting signal NPC.

Transistor T61 is connected between power supply line VDD, and bit line BL and bit line NBL. Specifically, transistor T61 is connected to bit line BL via transistor T51 and to bit line NBL via transistor T52. In other words, in accordance with signal A (signal NSLPPC), transistor T61 switches between supplying and not supplying a power supply voltage to first pre-charge circuit 152A. Specifically, the source of transistor T61 is connected to power supply line VDD, and the drain of transistor T61 is connected to power supply line NY. Signal A is supplied to the gate (control terminal) of transistor T61.

Transistor T62 is connected between power supply line VDD, and bit line BL and bit line NBL. Specifically, transistor T62 is connected to bit line BL via transistor T53 and to bit line NBL via transistor T54. In other words, in accordance with signal X, transistor T62 switches between supplying and not supplying the power supply voltage to second pre-charge circuit 153A. Specifically, the source of transistor T62 is connected to power supply line VDD, and the drain of transistor T62 is connected to power supply line NZ. Signal X is supplied to the gate (control terminal) of transistor T62. That is, transistor T61 and transistor T62 are connected in parallel between power supply line VDD, and bit line BL and bit line NBL.

Furthermore, transistor T62 has a drive performance higher than that of transistor T61. Here, the high and low levels of drive performance are adjusted by, for example, gate width/gate length (W/L) of a transistor, the threshold voltage of the transistor, or the level of a voltage applied to the gate or source of the transistor. It should be noted that the drive performance of transistor T62 may be the same as that of transistor T61 or lower than the driver performances of transistors T51 and T52.

First pre-charge circuit 152A is a circuit for pre-charging bit line BL and bit line NBL. First pre-charge circuit 152A includes transistors T51 and T52.

Transistor T51 is connected between power supply line NY and bit line BL. Specifically, the source of transistor T51 is connected to power supply line NY, and the drain of transistor T51 is connected to bit line BL. Signal B is supplied to the gate (control terminal) of transistor T51.

Transistor T52 is connected between power supply line NY and bit line NBL. Specifically, the source of transistor T52 is connected to power supply line NY, and the drain of transistor T52 is connected to bit line NBL. Signal B is supplied to the gate (control terminal) of transistor T52.

Second pre-charge circuit 153A is a circuit for pre-charging bit line BL and bit line NBL. Second pre-charge circuit 153A includes transistors T53, T54, and T55.

Transistor T53 is connected between power supply line NZ and bit line BL. Specifically, the source of transistor T53 is connected to power supply line NZ, and the drain of transistor T53 is connected to bit line BL. Signal B is supplied to the gate (control terminal) of transistor T53.

Transistor T54 is connected between power supply line NZ and bit line NBL. Specifically, the source of transistor T54 is connected to power supply line NZ, and the drain of transistor T54 is connected to bit line NBL. Signal B is supplied to the gate (control terminal) of transistor T54.

Transistor T55 is connected between bit line BL and bit line NBL. Signal B is supplied to the gate (control terminal) of transistor T55.

Furthermore, transistors T53 and T54 have drive performances higher than those of transistors T51 and T52. It should be noted that the drive performances of transistors T53 and T54 may be the same as or lower than those of transistors T51 and T52.

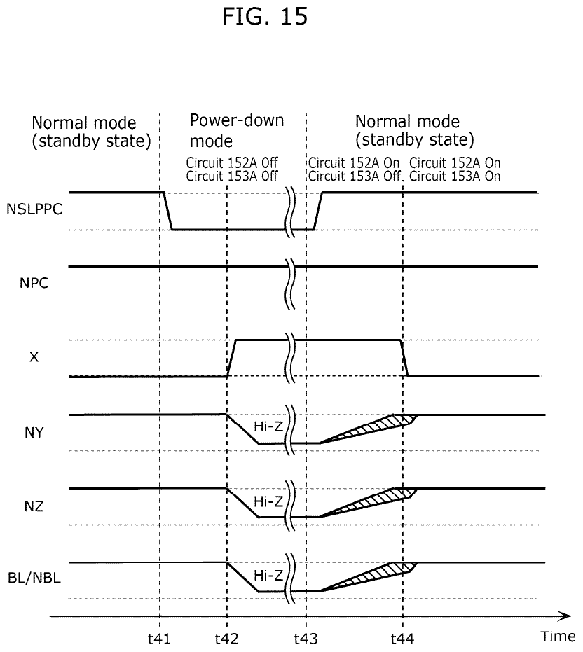

Then, an operation performed when switching the operation modes in variation 1 of input-output circuit 103B is described. FIG. 15 is a timing diagram illustrating an operation performed when switching the operation modes in variation 1 of input-output circuit 103B.

During the period before time t41 illustrated in FIG. 15, signal NSLPPC is at a high level, and semiconductor memory device 100B is operating in the normal mode. At time t41, signal NSLPPC changes from the high level to a low level, and the operation mode transitions to the power-down mode. When signal NSLPPC reaches the low level, signal A reaches the high level. Thus, transistor T61 is switched off.

Furthermore, signal X changes to the high level at time t42 later than signal A. When signal X reaches the high level, transistor T62 is switched off.

When transistor T61 and transistor T62 are switched off, power supply to first pre-charge circuit 152A and second pre-charge circuit 153A is cut off, which switches off first pre-charge circuit 152A and second pre-charge circuit 153A. Thus, bit line BL and bit line NBL are not pre-charged, and bit line BL and bit line NBL become the Hi-Z state.

At time t43, signal NSLPPC changes from the low level to the high level, and the operation mode transitions from the power-down mode to the normal mode. When signal NSLPPC reaches the high level, signal A reaches the low level. Thus, transistor T61 is switched on, and the voltage of power supply line NY starts increasing. Thus, first pre-charge circuit 152A is switched on, and first pre-charge circuit 152A starts pre-charging bit line BL and bit line NBL. In this way, the voltages of bit line BL and bit line NBL start increasing. Furthermore, a voltage is supplied to power supply line NZ from bit line BL and bit line NBL via second pre-charge circuit 153A, which increases the voltage of power supply line NZ.

Furthermore, signal X changes to the low level at time t44 later than signal A. When signal X reaches the low level, transistor T62 is switched on, and power is supplied from power supply line VDD to second pre-charge circuit 153A. Thus, second pre-charge circuit 153A is switched on, and first pre-charge circuit 152A and second pre-charge circuit 153A pre-charge bit line BL and bit line NBL.

Thus, in the period from time t43 to time t44 after the operation mode is switched from the power-down mode to the normal mode, transistor T61 is switched on, whereas transistor T62 is not switched on. That is, first pre-charge circuit 152A is switched on, whereas second pre-charge circuit 153A is not switched on. This can suppress the peak current when switching the operation modes. Furthermore, during the period after time t44, both transistor T61 and transistor T62 are on. Thus, both first pre-charge circuit 152A and second pre-charge circuit 153A are switched on. This enables voltage supply at a sufficient level.

As described above, semiconductor memory device 100B according to Embodiment 3 includes: memory cells 112; first pre-charge circuit 152 and second pre-charge circuit 153 (or first pre-charge circuit 152A and second pre-charge circuit 153A) that are connected to first bit line BL; and pre-charge control circuit 151 (or pre-charge control circuit 151A) that, in accordance with first signal NSLPPC for switching between the first mode (the normal mode) and the second mode (the power-down mode), (i) switches off first pre-charge circuit 152 and second pre-charge circuit 153 in the period of the second mode and (ii) switches on first pre-charge circuit 152 when switching from the second mode to the first mode is performed and switches on second pre-charge circuit 153 after first pre-charge circuit 152 is switched on, the first mode being a mode for pre-charging first bit line BL, the second mode being a mode for not pre-charging first bit line BL.

Thus, in semiconductor memory device 100B, first pre-charge circuit 152 is switched on when switching from the second mode to the first mode is performed, and then second pre-charge circuit 153 is switched on, which can suppress the peak current associated with power restoration. Furthermore, it is possible to suppress complication of control, compared with when blocks are controlled sequentially in time, for instance.

For instance, second pre-charge circuit 153 has a drive performance higher than that of first pre-charge circuit 152. Thus, it is possible to suppress the peak current efficiently.

For instance, pre-charge control circuit 151 includes delay circuit 156 (or delay circuit 162) that generates second signal X by delaying first signal NSLPPC. First pre-charge circuit 152 is switched between on and off in accordance with first signal NSLPPC (e.g., signal Y based on first signal NSLPPC). Second pre-charge circuit 153 is switched between on and off in accordance with second signal X (e.g., signal Z based on second signal X). Thus, it is possible to control first pre-charge circuit 152 and second pre-charge circuit 153 with a simple configuration.

For instance, semiconductor memory device 100B includes memory blocks each including memory cells 112 (e.g., memory cells 112 for each column). First pre-charge circuit 152 and second pre-charge circuit 153 are provided in each of (e.g., the columns of) the memory blocks. Second signal X generated by delay circuit 156 (e.g., signal Z based on second signal X) is supplied to the control terminal of each of two or more second pre-charge circuits 153 provided in two or more of the memory blocks. That is, delay circuit 156 is shared by, for example, a plurality of columns. Thus, the two or more memory blocks can share delay circuit 156, which results in reduction in circuit areas.

It should be noted that as with the circuit illustrated in FIG. 2, the circuits illustrated in FIGS. 12 and 14 have configurations where a control signal is generated using the delay circuit. However, as with the circuit illustrated in FIG. 5, a circuit using voltage detection may be used. For instance, in the example illustrated in FIG. 12, pre-charge control circuit 151 includes, instead of delay circuit 156, the voltage detection circuit that detects whether the voltage of bit line BL or bit line NBL is greater than or equal to a predetermined voltage. When signal NSLPPC is at the high level and the voltage of bit line BL or bit line NBL is greater than or equal to the predetermined voltage, pre-charge control circuit 151 switches on second pre-charge circuit 153. It should be noted that a given element can be used as the voltage detection circuit. For instance, a comparator, such as an operational amplifier, that compares a reference voltage and the voltage of bit line BL may be used.

That is, pre-charge control circuit 151 detects the voltage of first bit line BL. After pre-charge control circuit 151 switches on first pre-charge circuit 152 when the operation mode is switched from the second mode to the first mode, and when the voltage of bit line BL reaches the predetermined voltage, pre-charge control circuit 151 switches on second pre-charge circuit 153. Thus, it is possible to control first pre-charge circuit 152 and second pre-charge circuit 153 with high accuracy.

In addition, a control method for controlling semiconductor memory device 100B is a control method for controlling semiconductor memory device 100B that includes memory cells 112, bit line BL connected to memory cells 112, first pre-charge circuit 152, and second pre-charge circuit 153, the control method having the first mode (the normal mode) for pre-charging bit line BL and the second mode (the power-down mode) for not pre-charging bit line BL. The control method includes: pre-charging bit line BL by first pre-charge circuit 152 during a first period (e.g., t33 to t34 in FIG. 13) after switching from the second mode to the first mode is performed; and pre-charging bit line BL by first pre-charge circuit 152 and second pre-charge circuit 153 during a second period (e.g., the period after t34) after the first period.

Thus, in semiconductor memory device 100B, first pre-charge circuit 152 pre-charges bit line BL when the operation mode switches from the second mode to the first mode, and then first pre-charge circuit 152 and second pre-charge circuit 153 pre-charge bit line BL. In this way, it is possible to suppress the peak current associated with power restoration. Furthermore, it is possible to suppress complication of control, compared with when blocks are controlled sequentially in time, for instance.

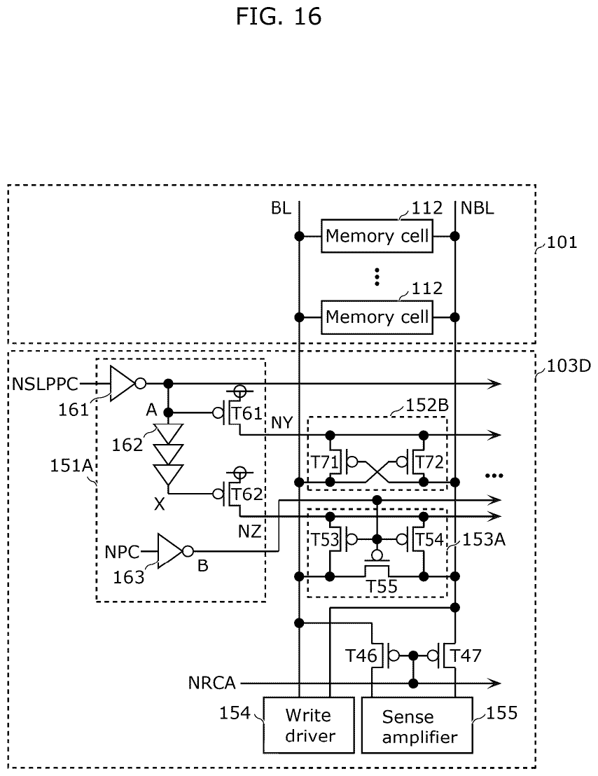

Variation 2 of input-output circuit 103B is described below. FIG. 16 illustrates a configuration of input-output circuit 103D, which is a variation of input-output circuit 103C. The configuration of first pre-charge circuit 152B included in input-output circuit 103D differs from that of first pre-charge circuit 152A included in input-output circuit 103C.

First pre-charge circuit 152B also serves as a cross-latch circuit for holding the voltage of the high-voltage-side bit line out of bit line BL and bit line NBL during data writing. First pre-charge circuit 152B includes transistors T71 and T72. The gate of transistor T71 is connected to bit line NBL, the source of transistor T71 is connected to power supply line NY, and the drain of transistor T71 is connected to bit line BL. The gate of transistor T72 is connected to bit line BL, the source of transistor T72 is connected to power supply line NY, and the drain of transistor T72 is connected to bit line NBL.

Thus, semiconductor memory device 100B further includes second bit line NBL connected to memory cells 112. First pre-charge circuit 152B includes first transistor T71 and second transistor T72. Here, one of the source or the drain of first transistor T71 is connected to first bit line BL, and the gate of first transistor T71 is connected to second bit line NBL. One of the source or the drain of transistor T72 is connected to second bit line NBL, and the gate of second transistor T72 is connected to first bit line BL. Thus, first pre-charge circuit 152B can also serve as a circuit for holding the voltages of first bit line BL and second bit line NBL, which can suppress circuit areas from increasing.

The semiconductor memory devices and the control methods thereof according to the embodiments of the present disclosure are described. However, the present disclosure is not limited to the embodiments.

It should be noted that the example in which switching between supplying and not supplying power to the memory cells is performed (Embodiments 1 and 2) and the example in which switching between pre-charging and not pre-charging the bit lines is performed (Embodiment 3) are separately described in the above. However, the semiconductor memory device may have both functions.

Furthermore, the semiconductor memory devices according to the embodiments are typically embodied as LSIs, which are integrated circuits. Integrated circuits may be made as individual chips, or some or all of the integrated circuits may be incorporated into one chip.

Furthermore, integration of circuits is not limited to an LSI, but may be achieved as a dedicated circuit or a general processor. A field programmable gate array (FPGA) that can be programmed after manufacturing an LSI, or a re-configurable processor in which connections and settings of circuit cells inside an LSI are reconfigurable may be used.

Furthermore, the present disclosure may be implemented as the control method for controlling the semiconductor memory device.

Furthermore, the functional-block division in each block diagram is an example. Two or more functional blocks may be embodied as one functional block. One functional block may be divided into two or more functional blocks. The functions of one or more functional blocks may be included in another functional block. Furthermore, the functions of two or more functional blocks having similar functions may be processed in parallel or on the time-sharing basis by single hardware or software.

Furthermore, the circuit configurations illustrated in, for example, the circuit diagrams are examples, and the present disclosure is not limited to the circuit configurations. That is, as with the circuit configurations, the present disclosure includes a circuit capable of achieving the distinctive functions of the present disclosure. For instance, within the scope where functions similar to those of the circuit configurations can be achieved, the present disclosure also includes a configuration in which an element, such as a switching element (a transistor), a resistance element, or a capacitative element, is connected to an element in series or in parallel. In other words, the term “connected” in the above embodiments is not limited to a case where two terminals (nodes) are directly connected to each other, but includes a case where the two terminals (the nodes) are connected to each other via an element within the scope where similar functions can be achieved.

Furthermore, all of the numbers used in the embodiments are provided for exemplification to specifically explain the present disclosure. Thus, the present disclosure is not limited to the exemplified numbers. Moreover, the logic levels represented by high and low or the switching states represented by on and off are provided for exemplification to specifically explain the present disclosure. It is possible to obtain equivalent results by a different combination of the exemplified logic levels or switching states. Moreover, the illustrated configuration of each logic circuit is provided for exemplification to specifically explain the present disclosure, and it is possible to achieve an equivalent input-output relationship with the use of a logic circuit of a different configuration. Furthermore, for example, the n type and p type of, for example, a transistor are provided for exemplification to specifically explain the present disclosure, and it is possible to obtain an equivalent result by inverting the n type and the p type.

The semiconductor memory device(s) and the control method(s) thereof according to one aspect or aspects are described on the basis of the embodiments. However, the present disclosure is not limited to the embodiments. The one aspect or the aspects may include, within the scope of the present disclosure, one or more embodiments obtained by making various changes envisioned by those skilled in the art to the embodiment(s) and one or more embodiments obtained by any combination of structural elements in different embodiments.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are Intended to be included within the scope of the present disclosure.

### INDUSTRIAL APPLICABILITY

The present disclosure is applicable to a semiconductor memory device.

1. A semiconductor memory device comprising:
a plurality of memory cells;
a first power supply line to which a power supply voltage is supplied;
a second power supply line serving as a power supply voltage line of the plurality of memory cells;
a first transistor and a second transistor that are connected in parallel between the first power supply line and the second power supply line; and
a control circuit that, in accordance with a first signal for switching between a first mode and a second mode, (i) switches off the first transistor and the second transistor in a period of the second mode and (ii) switches on the first transistor when switching from the second mode to the first mode is performed and switches on the second transistor after the first transistor is switched on, the first mode being a mode for supplying the power supply voltage to the plurality of memory cells, the second mode being a mode for not supplying the power supply voltage to the plurality of memory cells.

2. The semiconductor memory device according to claim 1,
wherein the second transistor has a drive performance higher than a drive performance of the first transistor.

3. The semiconductor memory device according to claim 1,
wherein the control circuit includes a delay circuit that generates a second signal by delaying the first signal,
the first signal is supplied to a control terminal of the first transistor, and
the second signal is supplied to a control terminal of the second transistor.

4. The semiconductor memory device according to claim 3, further comprising:
a plurality of memory blocks each including the plurality of memory cells,
wherein the first transistor and the second transistor are provided in each of the plurality of memory blocks, and
the second signal generated by the delay circuit is supplied to the control terminal of each of two or more second transistors provided in two or more of the plurality of memory blocks.

5. The semiconductor memory device according to claim 1,
wherein the control circuit detects a voltage of the second power supply line, and
after the first transistor is switched on when switching from the second mode to the first mode is performed, and when the voltage of the second power supply line reaches a predetermined voltage, the control circuit switches on the second transistor.

6. The semiconductor memory device according to claim 1, further comprising:
a write assist circuit that decreases, during data writing to the plurality of memory cells, a voltage of the second power supply line to a voltage lower than the voltage of the second power supply line at a time other than during the data writing,
wherein the write assist circuit includes the first transistor and the second transistor, and
one of the first transistor or the second transistor is off during the data writing.

7. A semiconductor memory device comprising:
a plurality of memory cells;
a first bit line connected to the plurality of memory cells;
a first pre-charge circuit and a second pre-charge circuit that are connected to the first bit line; and
a control circuit that, in accordance with a first signal for switching between a first mode and a second mode, (i) switches off the first pre-charge circuit and the second pre-charge circuit in a period of the second mode and (ii) switches on the first pre-charge circuit when switching from the second mode to the first mode is performed and switches on the second pre-charge circuit after the first pre-charge circuit is switched on, the first mode being a mode for pre-charging the first bit line, the second mode being a mode for not pre-charging the first bit line.

8. The semiconductor memory device according to claim 7,
wherein the second pre-charge circuit has a drive performance higher than a drive performance of the first pre-charge circuit.

9. The semiconductor memory device according to claim 7,
wherein the control circuit includes a delay circuit that generates a second signal by delaying the first signal,
the first pre-charge circuit is switched between on and off in accordance with the first signal, and
the second pre-charge circuit is switched between on and off in accordance with the second signal.

10. The semiconductor memory device according to claim 9, further comprising:
a plurality of memory blocks each including the plurality of memory cells,
wherein the first pre-charge circuit and the second pre-charge circuit are provided in each of the plurality of memory blocks, and
the second signal generated by the delay circuit is supplied to two or more pre-charge circuits provided in two or more of the plurality of memory blocks.

11. The semiconductor memory device according to claim 7,
wherein the control circuit detects a voltage of the first bit line, and
after the first pre-charge circuit is switched on when switching from the second mode to the first mode is performed, and when the voltage of the first bit line reaches a predetermined voltage, the control circuit switches on the second pre-charge circuit.

12. The semiconductor memory device according to claim 7, further comprising:
a second bit line connected to the plurality of memory cells,
wherein the first pre-charge circuit includes:
a first transistor that includes a source and a drain, one of which is connected to the first bit line, and a gate connected to the second bit line; and
a second transistor that includes a source and a drain, one of which is connected to the second bit line, and a gate connected to the first bit line.

13. A control method for controlling a semiconductor memory device that includes a plurality of memory cells, a first transistor, and a second transistor, the control method having a first mode for supplying a power supply voltage to the plurality of memory cells and a second mode for not supplying the power supply voltage to the plurality of memory cells, the control method comprising:
supplying the power supply voltage to the plurality of memory cells via the first transistor during a first period after switching from the second mode to the first mode is performed, and supplying the power supply voltage to the plurality of memory cells via the first transistor and the second transistor during a second period after the first period.
